(19) United States
(12) Patent Application Publication
(10) Pub. No.: US 2026/0304652 A1
(43) Pub. Date: Oct. 1, 2026

(54) LATCHING DEVICE

(71) Applicant: Delta Electronics (Thailand) Public Company Limited, Samutprakarn (TH)

(72) Inventors: Faxin Liu, Shanghai (CN); Liangsong Che, Shanghai (CN); Meng Wang, Shanghai (CN); Donglin Fu, Shanghai (CN)

(21) Appl. No.: 19/556,231

(22) Filed: Mar. 4, 2026

(30) Foreign Application Priority Data
Mar. 28, 2025 (CN) 202510386262.4
Mar. 28, 2025 (CN) 202520575256.9

(51) Int. Cl. H05K 5/02

(52) U.S. Cl. CPC H05K 5/0221

(57) ABSTRACT

A latching device is disclosed and disposed on an electrical unit. The latching device includes a movable component and a snap portion. The movable component is arranged adjacent to a front end of the electrical unit, and the snap portion is arranged on the movable component and allowed to protrude outward from a bottom plate or a top plate of the electrical unit. When the electrical unit is placed into a chassis accommodation seat along a first direction, the movable component maintains the snap portion to penetrate through the bottom plate or the top plate and engage with a snap slot on the chassis accommodation seat, so that the electrical unit is locked on the chassis accommodation seat.

### CROSS-REFERENCE TO RELATED APPLICATION

This application claims priority to China Patent Application No. 202520575256.9, filed on Mar. 28, 2025, and to China Patent Application No. 202510386262.4, filed on Mar. 28, 2025. The entire contents of the above-mentioned patent applications are incorporated herein by reference for all purposes.

### FIELD OF THE INVENTION

The present disclosure relates to the technical field of a latching device, and more particularly to a latching device applied to a power supply to solve the space utilization problem of electrical units.

### BACKGROUND OF THE INVENTION

In today's daily life, many electrical devices require power adapter modules to provide the required power. Taking the power supply unit of the server as an example, the power supply unit is usually fixed in the chassis accommodation seat through a latching device. Since the latching device is usually installed in the housing of the power supply unit, the inner space of the housing is occupied.

In the prior art, the latching device mainly includes an elastic plate and a snap protrusion. The elastic plate is installed on the lateral plate of the housing, and the snap protrusion is arranged perpendicular to the elastic plate, so that the pressing direction is perpendicular to the elongated direction of the elastic plate. Through the pressing action, the elastic plate is bent and deformed, and the snap protrusion is driven to move out of the receiving slot, so that the power supply unit can be placed into or removed from the chassis accommodation seat. Since the snap protrusion needs to be pressed during the plugging and unplugging of the power supply unit, a certain movement space needs to be reserved for the latching device in the width direction inside the housing of the power supply unit, so as to prevent the latching device from interfering with other parts inside the housing of the power supply unit. In addition, the locking between the power supply unit and the chassis accommodation seat is achieved through the latching device, and the space of the chassis accommodation seat is occupied for setting the latching device so that the width dimension of the power supply unit is limited. In the case of multiple chassis accommodation seats, two adjacent power supply units received are separated by a vertical partition. However, in order to prevent the two adjacent power supply units from interfering with each other, a certain width space is occupied for the thickness of the partition, so that the utilization of the overall space is affected.

On the other hand, the power supply units used in the servers are increasingly developed towards smaller size and higher power. Some power supply units are unable to meet the heat dissipation requirements by using one single fan. Therefore, two additional fans need to be used, but the two fans placed side by side horizontally will occupy the movement space of the latching device.

In view of this, there is a need of providing a latching device applied to an electrical unit to solve the space utilization problem of the electrical unit, and obviate the drawbacks encountered by the prior arts.

### SUMMARY OF THE INVENTION

An object of the present disclosure is to provide a latching device applied to an electrical unit. The latching device is arranged on the front side of the housing of the electrical unit, and is located on the bottom plate or the top plate of the inner surface of the housing. The fixed plate and the elastic plate of the latching device are integrally formed by a metal sheet, and the structure is strengthened by connecting a protrusion or a rib. The latching device is fixed to the side plate, the bottom plate or the top plate of the housing of the electrical unit through the fixed plate. Since the latching device is fixed to the housing of the electrical unit only by the fixed plate at one end, and the elastic plate is extended along the bottom plate or the top plate of the housing, the space utilization of the electrical unit in the width direction can be saved. It is beneficial to arrange the dual fans of the electrical unit in the width direction of the housing. Certainly, it allows to utilize the space in the elongated direction of the electrical unit to improve the overall space utilization of the electrical unit. The end surface of the fixed plate is attached to the side plate, the top plate or the bottom plate of the housing of the electrical unit and fixed by a fastening element such as a rivet. One end of the elastic plate is connected to the fixed plate, and the bottom surface of the elastic plate is located at the front end of the housing of the electrical unit and attached to the bottom plate or the top plate in the housing. The snap portion and the pressed plate are integrally formed by a metal sheet, then vertically disposed on the elastic plate through a fastening element such as a rivet, and fixed to an offset section of the elastic plate away from the fixed plate. The elastic plate is bent in advance. After the fixed plate is fixed to the side plate, the bottom plate or the top plate of the housing, the elastic force of the elastic plate is increased to contact the bottom plate or the top plate of the housing. In addition, an opening for the snap portion to extend out is disposed on the bottom plate or the top plate of the housing of the electrical unit, and it allows the snap portion to further engage with the snap slot on the chassis accommodation seat, so that the electrical unit is locked to the chassis accommodation seat. When the pressed plate is pressed or lifted to drive the elastic plate and the snap portion on the elastic plate to move, the interference between the snap portion and the chassis accommodation seat is removed. In that, the snap portion is disengaged from the snap slot, and it allows to detach the electrical unit from the chassis accommodation seat. A limitation plate is further disposed on the bottom plate or the top plate of the electrical unit, and spatially corresponding to the latching device, so that the movement of the latching device in the installation direction of the electrical unit is limited. The dual fan module and the latching device are free of overlapping or interfering in the installation direction. The arrangement of the latching device in the present disclosure enables the space in the width direction and the elongated direction inside the electrical unit to be effectively utilized, thereby improving the overall space utilization of the electrical unit. On the other hand, when the latching device is fixed to the side plate of the housing through the fixed plate, the pre-bent elastic plate is perpendicular to the fixed plate after installation and set at the bottom/top of the housing of the electrical unit, so that the impact resistance of the latching device is further enhanced, and the latching device is not easy to shake.

In accordance with an aspect of the present disclosure, a latching device disposed on an electrical unit is provided. The latching device includes a movable component and a snap portion. The movable component is arranged adjacent to a front end of the electrical unit, and the snap portion is arranged on the movable component and allowed to protrude outward from a bottom plate or a top plate of the electrical unit. When the electrical unit is placed into a chassis accommodation seat along a first direction, the movable component maintains the snap portion to penetrate through the bottom plate or the top plate and engage with a snap slot on the chassis accommodation seat, so that the electrical unit is locked on the chassis accommodation seat.

In an embodiment, the movable component includes a fixed plate, an elastic plate and a pressed plate. The fixed plate is fixed to a side plate of the electrical unit along a second direction, or fixed to the bottom plate or the top plate of the electrical unit along a third direction, wherein the first direction, the second direction and the third direction are perpendicular to each other. The elastic plate is extended along the third direction and disposed on the bottom plate or the top plate, and includes a first end and a second end, wherein the first end is connected to the fixed plate. The pressed plate is connected to the snap portion and the second end of the elastic plate, protrudes out of the front end of the electrical unit, and allows the elastic plate to be bent under force and drive the snap portion, so that the snap portion is disengaged from the snap slot and stored in the bottom plate or the top plate, wherein when the snap portion is disengaged from the snap slot, the electrical unit is allowed to be separated from the chassis accommodation seat.

In an embodiment, the electrical unit includes one of a power supply unit (PSU), a battery backup unit (BBU) and a capacitance backup unit (CBU).

In an embodiment, when the electrical unit is locked in the chassis accommodation seat, a rear end of the electrical unit is electrically connected to the chassis accommodation seat, and the front end and the rear end are two opposite ends in the first direction.

In an embodiment, the fixed plate is fixed to the side plate, the bottom plate or the top plate through a fastening element.

In an embodiment, the fixed plate and the elastic plate are integrally formed by a metal sheet.

In an embodiment, the electrical unit further includes a limitation plate, which is extended along the third direction and arranged on the bottom plate or the top plate, perpendicular to the bottom plate or the top plate, protruding toward an interior of the electrical unit, and arranged adjacent to a lateral edge of the elastic plate to limit a movement of the elastic plate in the first direction.

In an embodiment, the elastic plate further includes a folded edge structure, which is disposed adjacent to the lateral edge of the elastic plate.

In an embodiment, the elastic plate includes a first surface and a second surface opposite to each other, and the first surface is close to the bottom plate or the top plate.

In an embodiment, the elastic plate further includes a rib disposed on the second surface of the elastic plate and extended along the third direction.

In an embodiment, the elastic plate further includes an offset section located at the second end, the offset section is offset toward the second surface to form a step, and the pressed plate is connected to the first surface in the offset section.

In an embodiment, the pressed plate is fixed to the first surface in the offset section through a fastening element.

In an embodiment, the snap portion has a protruding height relative to the first surface of the elastic plate, and the protruding height is ranged from 2 mm to 4 mm.

In an embodiment, the pressed plate further includes a pressed portion, which is offset from the first surface toward the second surface to form a step.

In an embodiment, the pressed portion is forced to move from the first surface toward the second surface to resist an elastic restoring force of the elastic plate and drive the snap portion at the second end to separate from the snap slot.

In an embodiment, the elastic plate further includes a bent portion arranged adjacent to the first end and pre-bending the first surface, wherein when the fixed plate is fixed to the side plate, the first surface of the elastic plate is in contact with the bottom plate or the top plate, and an elastic force is provided by the elastic plate to maintain the snap portion penetrating the bottom plate.

In an embodiment, the latching device further includes a connection protrusion disposed between the fixed plate and the first end of the elastic plate.

In an embodiment, the electrical unit includes at least one fan module disposed between the side plate and an opposite side plate, adjacent to the front end and arranged along the third direction, and wherein the latching device and the at least one fan module are arranged along the first direction.

In an embodiment, the snap portion and the pressed plate are integrally formed by a metal sheet.

In an embodiment, the pressed plate is fixed to the second end of the elastic plate through a fastening element.

The beneficial effect of the present disclosure is that the embodiments of the present disclosure provide a latching device applied to an electrical unit to solve the space utilization problem of the power supply unit (PSU), the battery backup unit (BBU), and the capacitance backup unit (CBU). Through the arrangement of the latching device of the present disclosure, the space in the width direction of the electrical unit is fully utilized to achieve the locking of the electrical unit to the chassis, and the space utilization of the electrical unit is improved at the same time. Furthermore, the pre-bent elastic plate is maintained perpendicular to the fixed plate after installation, and disposed at the bottom plate or the top plate of the housing of the electrical unit, thereby further enhancing the impact resistance of the latching device and preventing the latching device from shaking.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a structural perspective view illustrating an electrical unit locked to a chassis accommodation seat through a latching device according to an embodiment of the present disclosure;

FIG. 2 is a structural perspective view illustrating the electrical unit combined with the latching device according to the embodiment of the present disclosure;

FIG. 3 is a structural exploded view illustrating the internal components of the electrical unit corresponding to the latching device according to the embodiment of the present disclosure;

FIG. 4 is a front view illustrating the latching device according to the embodiment of the present disclosure;

FIG. 5 is a structural perspective view illustrating the latching device fixed to the electrical unit according to the embodiment of the present disclosure;

FIG. 6 is a front view illustrating the latching device fixed to the electrical unit according to the embodiment of the present disclosure;

FIG. 7 schematically shows the electrical unit being locked in the chassis accommodation seat through the latching device according to the embodiment of the present disclosure;

FIG. 8 schematically shows the latching device releasing interference and allowing the electrical unit to move out of the corresponding chassis accommodation seat according to the embodiment of the present disclosure;

FIG. 9 is a structural perspective view illustrating a latching device according to another embodiment of the present disclosure; and

FIG. 10 is a structural perspective view illustrating a latching device according to a further embodiment of the present disclosure.

### DETAILED DESCRIPTION

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed. Further, spatially relative terms, such as “upper,” “lower,” “front,” “rear,” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items. Alternatively, the word “about” means within an acceptable standard error of ordinary skill in the art-recognized average. In addition to the operation/working examples, or unless otherwise specifically stated otherwise, in all cases, all of the numerical ranges, amounts, values and percentages, such as the number for the herein disclosed materials, time duration, temperature, operating conditions, the ratio of the amount, and the like, should be understood as the word “about” decorator. Accordingly, unless otherwise indicated, the numerical parameters of the present disclosure and scope of the appended patent proposed is to follow changes in the desired approximations. At least, the number of significant digits for each numerical parameter should at least be reported and explained by conventional rounding technique is applied. Herein, it can be expressed as a range between from one endpoint to the other or both endpoints. Unless otherwise specified, all ranges disclosed herein are inclusive.

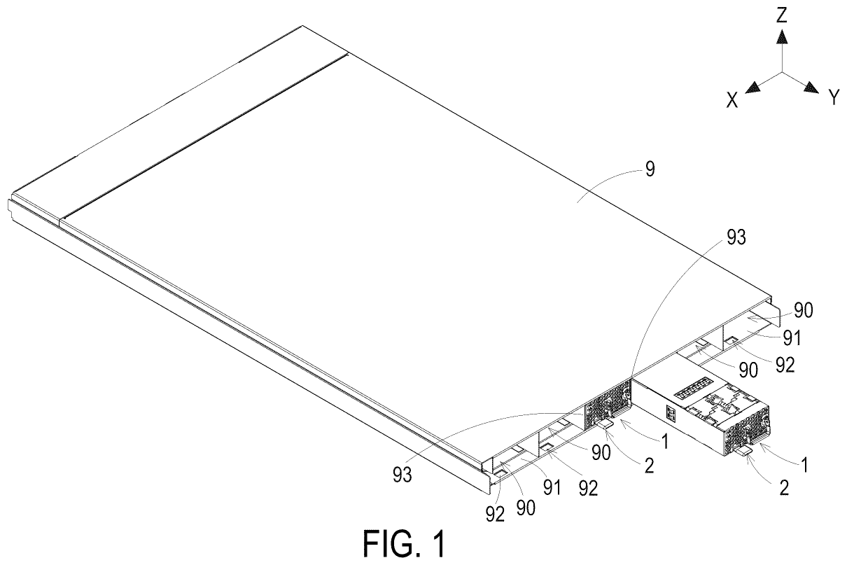

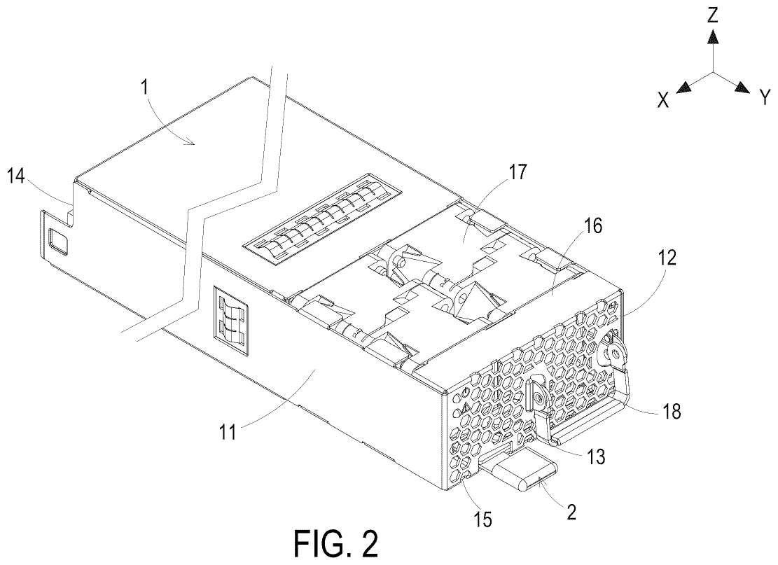

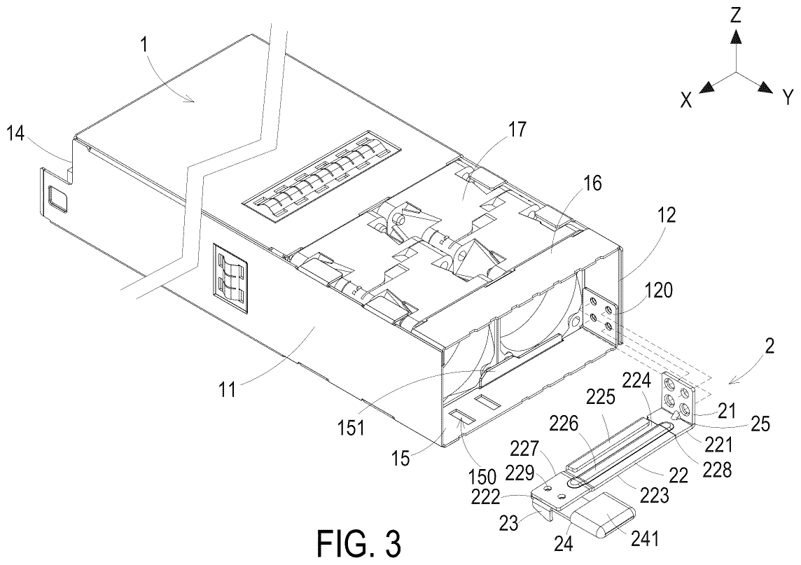

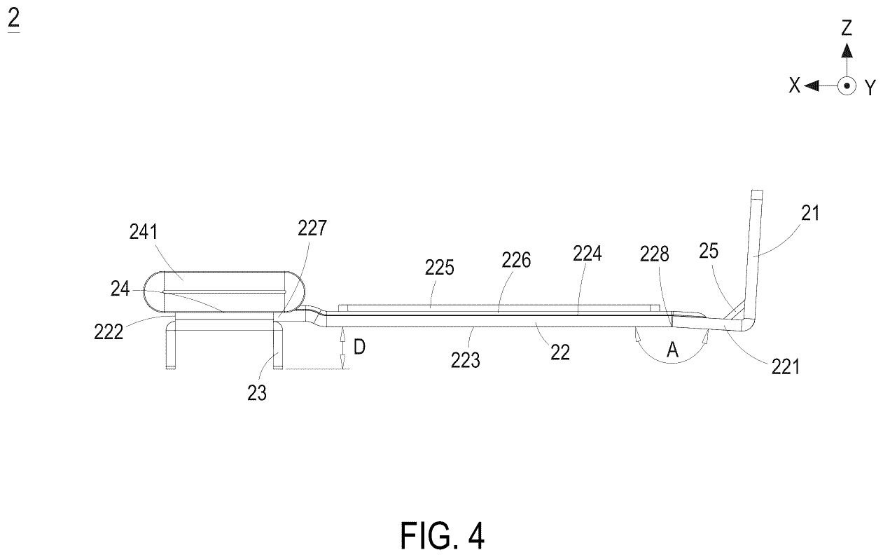

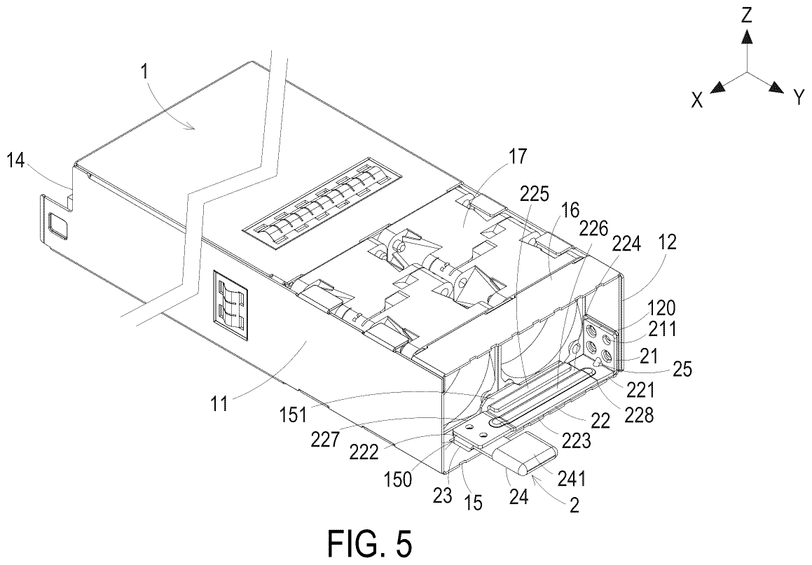

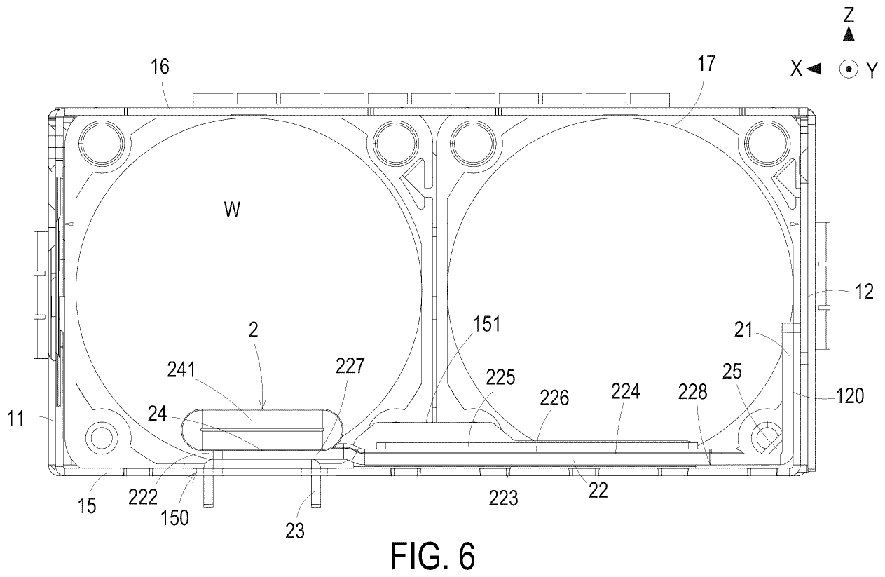

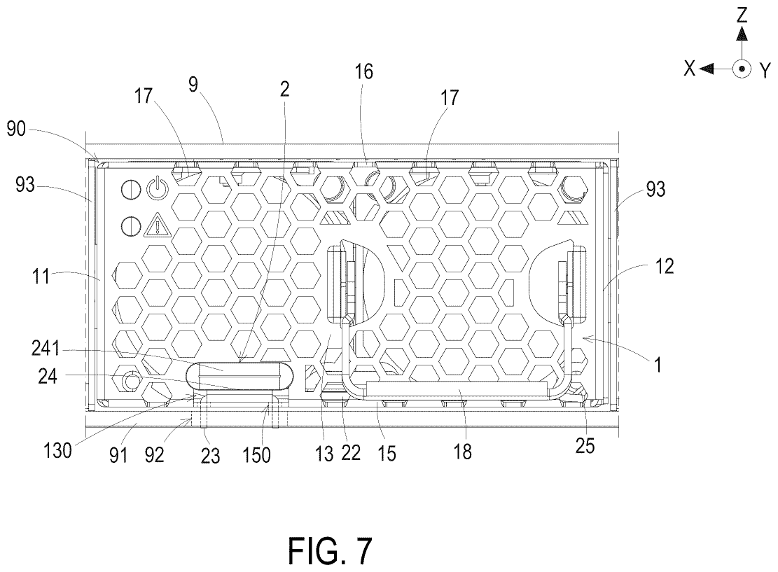

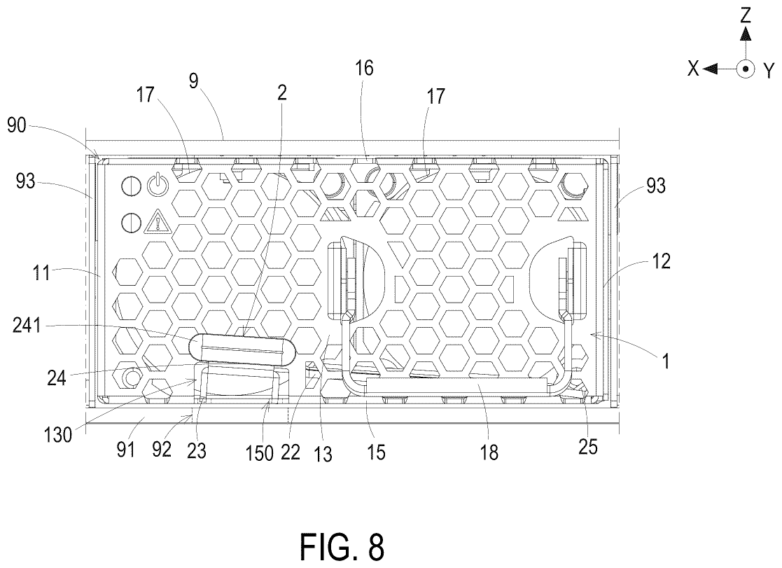

FIG. 1 is a structural perspective view illustrating an electrical unit locked to a chassis accommodation seat through a latching device according to an embodiment of the present disclosure. FIG. 2 is a structural perspective view illustrating the electrical unit combined with the latching device according to the embodiment of the present disclosure. FIG. 3 is a structural exploded view illustrating the internal components of the electrical unit corresponding to the latching device according to the embodiment of the present disclosure. FIG. 4 is a front view illustrating the latching device according to the embodiment of the present disclosure. FIG. 5 is a structural perspective view illustrating the latching device fixed to the electrical unit according to the embodiment of the present disclosure. FIG. 6 is a front view illustrating the latching device fixed to the electrical unit according to the embodiment of the present disclosure. FIG. 7 schematically shows the electrical unit being locked in the chassis accommodation seat through the latching device according to the embodiment of the present disclosure. FIG. 8 schematically shows the latching device releasing interference and allowing the electrical unit to move out of the corresponding chassis accommodation seat according to the embodiment of the present disclosure. In the embodiment, the present disclosure provides a latching device 2 disposed on an electrical unit 1. Preferably but not exclusively, the electrical unit 1 includes one of a power supply unit (PSU), a battery backup unit (BBU) and a capacitance backup unit (CBU). In the embodiment, the electrical unit 1 includes a first side plate 11 and a second side plate 12 opposite to each other, and the first side plate 11 and the second side plate 12 are connected through a bottom plate 15 and a top plate 16. When a rear end 14 of the electrical unit 1 is aligned with one of chassis accommodation seats 90 in the cabinet 9, the electrical unit 1 can be placed into the corresponding chassis accommodation seat 90 along the first direction (i.e., the inverse Y-axis direction). When a front end 13 of the electrical unit 1 is attached to the opening of the chassis accommodation seat 90, the electrical unit 1 can be locked on the chassis accommodation seat 90 through the latching device 2. In the embodiment, a plurality of chassis accommodation seats 90 are arranged side by side along the X-axis direction and have the same structure. A partition plate 93 is disposed between each adjacent two of the chassis accommodation seats 90. In the embodiment, the latching device 2 is disposed adjacent to the front end 13 of the electrical unit 1 and includes a movable component and a snap portion 23. The movable component at least includes a fixed plate 21, an elastic plate 22 and a pressed plate 24. The movable component is disposed adjacent to the front end 13 of the electrical unit 1. The snap portion 23 is disposed on the movable component, and allowed to protrude outward from the bottom plate 15 or the top plate 16 of the electrical unit 1. In the embodiment, when the electrical unit 1 is placed into the chassis accommodation seat 90 along the first direction (i.e., the inverse Y-axis direction), the elastic plate 22 of the movable component maintains the snap portion 23 to penetrate the bottom plate 15 or the top plate 16 and engage with the snap slot 92 on the chassis accommodation seat 90, so that the electrical unit 1 is locked to the chassis accommodation seat 90. In the embodiment, the fixed plate 21 is extended along the second direction (i.e., the Z-axis direction) and fixed to the second side plate 12 of the electrical unit 1 by a fastening element 211, such as a rivet. In another embodiment, the fixed plate 21 is extended along the third direction (i.e., the X-direction) and fixed to the bottom plate 15 or the top plate 16 of the electrical unit 1 by a fastening element such as a rivet (not shown). The first direction, the second direction and the third direction are perpendicular to each other. The elastic plate 22 is extended along the third direction (i.e., the X-axis direction) and disposed on the bottom plate 15 of the electrical unit 1. The elastic plate 22 has a first end 221 and a second end 222 opposite to each other. The first end 221 of the elastic plate 22 is connected to the fixed plate 21. In addition, the snap portion 23 is disposed at the second end 222 of the elastic plate 22, and allowed to protrude outward from the bottom plate 15 of the electrical unit 1 through the opening 150 of the bottom plate 15. When the electrical unit 1 is accommodated in the chassis accommodation seat 90, an elastic force is provided by the elastic plate 22 to maintain the snap portion 23 penetrating the bottom plate 15 to engage with the snap slot 92 on the bottom 91 of the chassis accommodation seat 90, so that the electrical unit 1 is locked to the chassis accommodation seat 90. In the embodiment, the pressed plate 24 is connected to the second end 222 of the elastic plate 22, protrudes out of the front end 13 of the electrical unit 1 along the Y-axis direction. Moreover, the pressed plate 24 is further exposed through the window 130. It allows the elastic plate 22 to be bent under force and drive the snap portion 23, so that the snap portion 23 is disengaged from the snap slot 92 and stored in the bottom plate 15. Furthermore, when the snap portion 23 of the latching device 2 is separated from the snap slot 92 of the chassis accommodation seat 90, the electrical unit 1 is allowed to be separated from the chassis accommodation seat 90 along the Y-axis direction.

Preferably but not exclusively, in the embodiment, the electrical unit 1 has a rectangular structure. The assembling method of the first side plate 11, the second side plate 12, the bottom plate 15 and the top plate 16 is not an essential technical feature to limit the present disclosure, and thus will not be described in detail. In the embodiment, when the electrical unit 1 is locked in the chassis accommodation seat 90, the rear end 14 of the electrical unit 1 is further electrically connected to the connector behind the chassis accommodation seat 90. The front end 13 and the rear end 14 are two opposite ends in the first direction (i.e., the inverse Y-axis direction). The structures of the front end 13 and the rear end 14 of the electrical unit 1 are not essential technical features to limit the present disclosure and adjustable according to the practical requirements. For example, the front end 13 of the electrical unit 1 has a ventilation grille and a handle 18 disposed thereon. Preferably but not exclusively, the latching device 2 is partially extended through the window 130 of the front end 13. For ease of explanation, a part of the structure of the front end 13 is omitted, as shown in FIG. 3, FIG. 5 and FIG. 6, but is not intended to limit the present disclosure. Notably, in addition, the latching device 2 of the present disclosure is disposed adjacent to the front end 13 of the electrical unit 1, and spatially corresponding to a vertical side plate (parallel to the Z-axis direction) and a connection horizontal plate (parallel to the X-axis direction) of the electrical unit 1. In the following embodiments, although the fixed plate 21 and the elastic plate 22 of the latching device 2 correspond to the second side plate 12 and the bottom plate 15 of the electrical unit 1 for illustration, the present disclosure is not limited thereto. For example, in some embodiments, the fixed plate 21 and the elastic plate 22 of the latching device 2 correspond to the bottom plate 15 or the top plate 16 of the electrical unit 1 at the same time. In other embodiments, the fixed plate 21 and the elastic plate 22 are respectively arranged and corresponding to the first side plate 11 and the top plate 16 of the electrical unit 1, the first side plate 11 and the bottom plate 15 of the electrical unit 1, or the second side plate 12 and the top plate 16 of the electrical unit 1. The explanation is provided in advance.

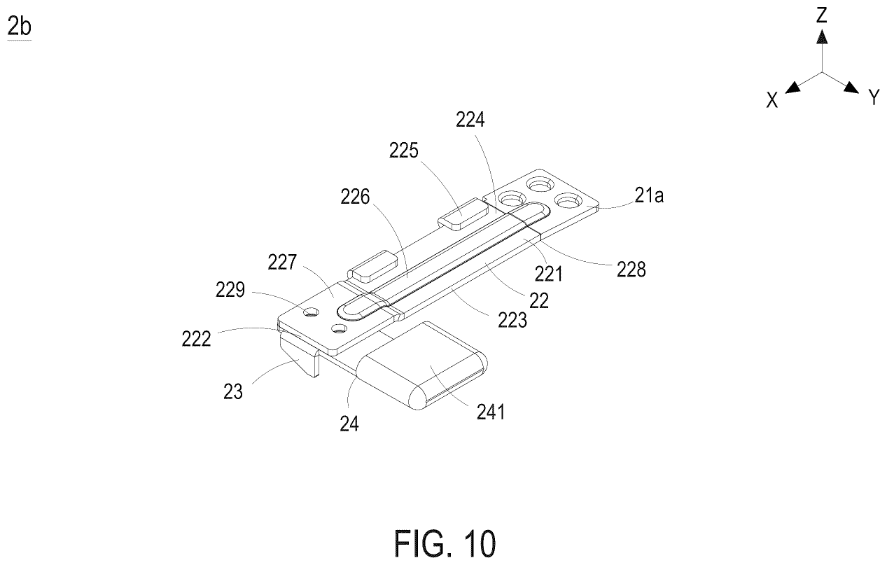

Preferably but not exclusively, in the embodiment, the fixed plate 21 and the elastic plate 22 of the latching device 2 are integrally formed by a metal sheet. In case of that the fixed plate 21 and the elastic plate 22 of the latching device 2 correspond to the second side plate 12 and the bottom plate 15 of the electrical unit 1 respectively, the fixed plate 21 is fixed to the inner wall surface 120 of the second side plate 12 by a fastening element 211, such as a rivet, and the fixed plate 21 and the elastic plate 22 are in an “L” shape in view of the first direction (i.e., the inverse Y-axis direction). In case of that the fixed plate 21 is fixed to the second bottom plate 15 or the top plate 16 of the electrical unit 1 along the third direction (i.e., the X-axis direction), the fixed plate 21 and the elastic plate 22 form an “I” shape in view of the first direction (i.e., the inverse Y-axis direction) or in view of an opposite direction (i.e., the Y-axis direction). At this time, a fixed end 21a (Refer to FIG. 10) formed by the first end 221 of the elastic plate 22 is regarded as the fixed plate 21.

Notably, in the embodiment, the elastic plate 22 includes a first surface 223 and a second surface 224 opposite to each other. The first surface 223 is attached to the bottom plate 15 of the electrical unit 1. The elastic plate 22 further includes a bent portion 228, which is disposed adjacent to the first end 221 of the elastic plate 22, and pre-bends the first surface 223 to form a bent angle A. In this way, when the fixed plate 21 is fixed to the inner wall surface 120 of the second side plate 12 by, for example but not limited to, rivets or other fastening elements, the first surface 223 of the elastic plate 22 is in contact with the inner wall surface of the bottom plate 15, thereby increasing the elastic force to maintain the snap portion 23 of the latching device 2 passing through the opening 150 of the bottom plate 15. In the embodiment, when the electrical unit 1 is placed in one of the plurality of chassis accommodation seats 90 arranged side by side, the elastic plate 22 of the latching device 2 further maintains the snap portion 23 to penetrate the bottom plate 15, so that the snap portion 23 is engaged with the snap slot 92 on the bottom 91 of the chassis accommodation seat 90 to generate the interference. Since the latching device 2 is fixed to the second side plate 12 only by the fixed plate 21 at one end, the elastic plate 22, the snap portion 23 and the pressed plate 24 are all arranged relative to the bottom plate 15, so that the space utilization of the electrical unit 1 in the width direction is saved. It helps to achieve the installation of multiple electrical units 1, and solve the space utilization problem of the electrical unit 1 at the same time.

Furthermore, the pre-bent elastic plate 22 is maintained perpendicular to the fixed plate 21 after installation and set at the bottom plate 15 of the electrical unit 1, so that the impact resistance of the latching device 2 is enhanced, and the latching device 2 is not easy to shake. In the embodiment, the electrical unit 1 further includes a limitation plate 151, which is extended along the third direction (i.e., the X-axis direction) and arranged on the bottom plate 15, perpendicular to the bottom plate 15, protruding toward an interior of the electrical unit 1 along the Z-axis direction, and arranged adjacent to a lateral edge of the elastic plate 22 to limit a movement of the elastic plate 22 in the first direction (i.e., the inverse Y-axis direction). Consequently, the impact resistance of the latching device 2 is further enhanced. Moreover, it prevents the latching device 2 from shaking when the electrical unit 1 is placed into the chassis accommodation seat 90 along the first direction (i.e., the inverse Y-axis direction). In addition, in the embodiment, the elastic plate 22 further includes a folded edge structure 225, which is disposed adjacent to the lateral edge of the elastic plate 22. It helps the operator to press/lift the pressed plate 24, so that the elastic plate 22 is moved smoothly relative to the bottom plate 15 and the limitation plate 151. Certainly, the present disclosure is not limited thereto.

In the embodiment, the elastic plate 22 includes a first surface 223 and a second surface 224 opposite to each other. The first surface 223 is attached to the bottom plate 15 of the electrical unit 1. In order to enable the elastic plate 22 of the latching device 2 to maintain the snap portion 23 to penetrate the bottom plate 15 and engage with the snap slot 92 on the bottom 91 of the chassis accommodation seat 90 to generate the interference, the snap portion 23 of the latching device 2 has a protruding height D relative to the first surface 223 of the elastic plate 22, and the protruding height D is ranged from 2 mm to 4 mm. Certainly, the type and the size of the snap portion 23 are adjustable according to the practical requirements.

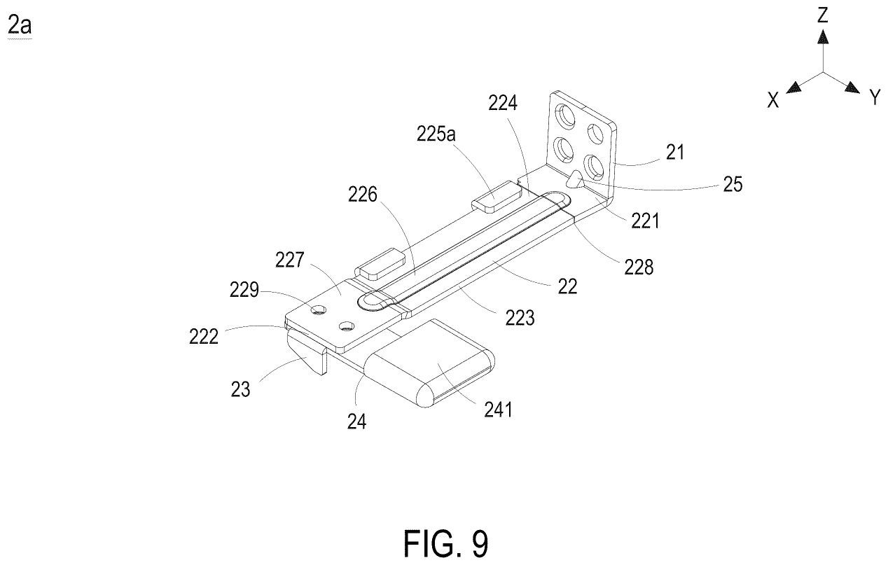

In the embodiment, the elastic plate 22 further includes a rib 226 disposed on the second surface 224 of the elastic plate 22 and extended along the third direction (i.e., the X-axis direction). By disposing the rib 226, the structural strength of the elastic plate 22 is further enhanced. Furthermore, the latching device 2 further includes a connection protrusion 25 disposed between the fixed plate 21 and the first end 221 of the elastic plate 22 to maintain the fixe plate 21 and the elastic plate 22 perpendicular to each other and enhance the overall structural strength of the latching device 2. In other embodiments, the elongated ranges of the aforementioned folded edge structure 225 and the rib 226 extended along the third direction (i.e., the X-axis direction) are adjustable according to the practical requirements, and can be set in multiple sections. The multi-section folded edge structure 225 or the multi-section ribs 226 are extended sequentially along the third direction (i.e., the X-axis direction). FIG. 9 is a structural perspective view illustrating a latching device according to another embodiment of the present disclosure. In the embodiment, the folded edge structure 225a of the elastic plate 22 is not bent in the middle section, but bent at two ends to form a segmented structure. In this way, the structural strength of the elastic plate 22 can be appropriately increased, thereby facilitating the pressing operation of the latching device 2a. Certainly, the present disclosure is not limited thereto.

In the embodiment, the pressed plate 24 includes a pressed portion 241, which is offset from the first surface 223 toward the second surface 224 of the elastic plate 22 to form a step. Moreover, in the embodiment, the elastic plate 22 further includes an offset section 227 located at the second end 222. The offset section 227 is offset toward the second surface 224 to form a step. The pressed plate 24 is connected to the first surface 223 in the offset section 227. Preferably but not exclusively, in the embodiment, the snap portion 23 and the pressed plate 24 are integrally formed by a metal sheet, and the pressed plate 24 is fixed to the first surface 223 in the offset section 227 through a fastening element 229, such as a rivet or other fastening element. That is, the snap portion 23 and the pressed plate 24 are disposed at the second end 222 of the elastic plate 22. When the pressed portion 241 is forced to move from the first surface 223 toward the second surface 224 (i.e., the Z-axis direction), it resists the elastic restoring force of the elastic plate 22 and drives the snap portion 23 at the second end 222 to disengage from the snap slot 92 at the bottom 91 of the chassis accommodation seat 90. Then, it allows the operator to use the handle 18 to move the electrical unit 1 out of the chassis accommodation seat 90 of the cabinet 9 along the Y-axis direction.

From the above, the latching device 2 of the present disclosure can be used along the bottom plate 15 or the top plate 16 of the electrical unit 1 to fully utilize the space in the width direction of the electrical unit 1. It allows to achieve the locking of the electrical unit 1 to the cabinet 9 and improve the space utilization of the electrical unit 1 at the same time. In the embodiment, the first side plate 11 and the second side plate 12 of the electrical unit 1 are opposite to each other and have a width distance W. By controlling the length of the elastic plate 22 of the latching device 2 within the width distance W, the electrical unit 1 can be firmly locked in the housing accommodation seat 90 of the cabinet 9, and the space utilization of the electrical unit 1 is improved. In the embodiment, the electrical unit 1 includes at least one fan module 17 disposed between the first side plate 11 and the second side plate 12. In the embodiment, two sets of fan modules 17 are disposed adjacent to the front end 13 and arranged along the third direction (i.e., the X-axis direction). Furthermore, in the embodiment, the latching device 2 and the fan modules 17 are arranged along the first direction (i.e., the inverse Y-axis direction) without overlapping or interfering with each other. The two sets of fan modules 17 are free of overlapping or interfering with the latching device 2 in the installation direction (i.e., the inverse Y-axis direction). The arrangement of the latching device 2 in the present disclosure enables the space in the width direction and the elongated direction inside the electrical unit 1 to be effectively utilized, thereby improving the overall space utilization of the electrical unit 1. Certainly, the present disclosure is not limited thereto and not redundantly described herein.

In summary, the present disclosure provides a latching device applied to an electrical unit to solve the space utilization problem of the power supply unit, the battery backup unit and the capacitance backup unit. The latching device is arranged on the front side of the housing of the electrical unit, and is located on the bottom plate or the top plate of the inner surface of the housing. The fixed plate and the elastic plate of the latching device are integrally formed by a metal sheet, in an “L” shape or an “I” shape, and the structure is strengthened by connecting a protrusion or a rib. The latching device is fixed to the side plate, the bottom plate or the top plate of the housing of the electrical unit through the fixed plate. Since the latching device is fixed to the housing of the electrical unit only by the fixed plate at one end, and the elastic plate is extended along the bottom plate or the top plate of the housing, the space utilization of the electrical unit in the width direction can be saved. It is beneficial to arrange the dual fans of the electrical unit in the width direction of the housing. Certainly, it allows to utilize the space in the elongated direction of the electrical unit to improve the overall space utilization of the electrical unit. The end surface of the fixed plate is attached to the side plate, the top plate or the bottom plate of the housing of the electrical unit and fixed by a fastening element such as a rivet. One end of the elastic plate is connected to the fixed plate, and the bottom surface of the elastic plate is located at the front end of the housing of the electrical unit and attached to the bottom plate or the top plate in the housing. The snap portion and the pressed plate are integrally formed by a metal sheet, then vertically disposed on the elastic plate through a fastening element such as a rivet, and fixed to an offset section of the elastic plate away from the fixed plate. The elastic plate is bent in advance. After the fixed plate is fixed to the side plate, the bottom plate or the top plate of the housing, the elastic force of the elastic plate is increased to contact the bottom plate or the top plate of the housing. In addition, an opening for the snap portion to extend out is disposed on the bottom plate or the top plate of the housing of the electrical unit, and it allows the snap portion to further engage with the snap slot on the chassis accommodation seat, so that the electrical unit is locked to the chassis accommodation seat. When the pressed plate is pressed or lifted to drive the elastic plate and the snap portion on the elastic plate to move, the interference between the snap portion and the chassis accommodation seat is removed. In that, the snap portion is disengaged from the snap slot, and it allows to detach the electrical unit from the chassis accommodation seat. A limitation plate is further disposed on the bottom plate or the top plate of the electrical unit, and spatially corresponding to the latching device, so that the movement of the latching device in the installation direction of the electrical unit is limited. The dual fan module and the latching device are free of overlapping or interfering in the installation direction. The arrangement of the latching device in the present disclosure enables the space in the width direction and the elongated direction inside the electrical unit to be effectively utilized, thereby improving the overall space utilization of the electrical unit. On the other hand, when the latching device is fixed to the side plate of the housing through the fixed plate, the pre-bent elastic plate is perpendicular to the fixed plate after installation and set at the bottom/top of the housing of the electrical unit, so that the impact resistance of the latching device is further enhanced, and the latching device is not easy to shake.

It should be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A latching device, disposed on an electrical unit and comprising:
a movable component and a snap portion, wherein the movable component is arranged adjacent to a front end of the electrical unit, and the snap portion is arranged on the movable component and allowed to protrude outward from a bottom plate or a top plate of the electrical unit, wherein when the electrical unit is placed into a chassis accommodation seat along a first direction, the movable component maintains the snap portion to penetrate through the bottom plate or the top plate and engage with a snap slot on the chassis accommodation seat, so that the electrical unit is locked on the chassis accommodation seat.

2. The latching device according to claim 1, wherein the movable component comprises:
a fixed plate fixed to a side plate of the electrical unit along a second direction, or fixed to the bottom plate or the top plate of the electrical unit along a third direction, wherein the first direction, the second direction and the third direction are perpendicular to each other;
an elastic plate, extended along the third direction and disposed on the bottom plate or the top plate, and comprising a first end and a second end, wherein the first end is connected to the fixed plate; and
a pressed plate connected to the snap portion and the second end of the elastic plate, protruding out of the front end of the electrical unit, and allowing the elastic plate to be bent under force and drive the snap portion, so that the snap portion is disengaged from the snap slot and stored in the bottom plate or the top plate, wherein when the snap portion is disengaged from the snap slot, the electrical unit is allowed to be separated from the chassis accommodation seat.

3. The latching device according to claim 2, wherein the fixed plate is fixed to the side plate, the bottom plate or the top plate through a fastening element.

4. The latching device according to claim 2, wherein the fixed plate and the elastic plate are integrally formed by a metal sheet.

5. The latching device according to claim 2, wherein the electrical unit further comprises a limitation plate, which is extended along the third direction and arranged on the bottom plate or the top plate, perpendicular to the bottom plate or the top plate, protruding toward an interior of the electrical unit, and arranged adjacent to a lateral edge of the elastic plate to limit a movement of the elastic plate in the first direction.

6. The latching device according to claim 5, wherein the elastic plate further comprises a folded edge structure, which is disposed adjacent to the lateral edge of the elastic plate.

7. The latching device according to claim 2, wherein the elastic plate comprises a first surface and a second surface opposite to each other, and the first surface is close to the bottom plate or the top plate.

8. The latching device according to claim 7, wherein the elastic plate further comprises a rib disposed on the second surface of the elastic plate and extended along the third direction.

9. The latching device according to claim 7, wherein the elastic plate further comprises an offset section located at the second end, the offset section is offset toward the second surface to form a step, and the pressed plate is connected to the first surface in the offset section.

10. The latching device according to claim 9, wherein the pressed plate is fixed to the first surface in the offset section through a fastening element.

11. The latching device according to claim 7, wherein the snap portion has a protruding height relative to the first surface of the elastic plate, and the protruding height is ranged from 2 mm to 4 mm.

12. The latching device according to claim 7, wherein the pressed plate further comprises a pressed portion, which is offset from the first surface toward the second surface to form a step.

13. The latching device according to claim 12, wherein the pressed portion is forced to move from the first surface toward the second surface to resist an elastic restoring force of the elastic plate and drive the snap portion at the second end to separate from the snap slot.

14. The latching device according to claim 7, wherein the elastic plate further comprises a bent portion arranged adjacent to the first end and pre-bending the first surface, wherein when the fixed plate is fixed to the side plate, the first surface of the elastic plate is in contact with the bottom plate or the top plate, and an elastic force is provided by the elastic plate to maintain the snap portion penetrating the bottom plate.

15. The latching device according to claim 2, further comprising a connection protrusion disposed between the fixed plate and the first end of the elastic plate.

16. The latching device according to claim 2, wherein the electrical unit comprises at least one fan module disposed between the side plate and an opposite side plate, adjacent to the front end and arranged along the third direction, and wherein the latching device and the at least one fan module are arranged along the first direction.

17. The latching device according to claim 2, wherein the snap portion and the pressed plate are integrally formed by a metal sheet.

18. The latching device according to claim 2, wherein the pressed plate is fixed to the second end of the elastic plate through a fastening element.

19. The latching device according to claim 1, wherein the electrical unit comprises one of a power supply unit (PSU), a battery backup unit (BBU), and a capacitance backup unit (CBU).

20. The latching device according to claim 1, wherein when the electrical unit is locked in the chassis accommodation seat, a rear end of the electrical unit is electrically connected to the chassis accommodation seat, and the front end and the rear end are two opposite ends in the first direction.
